(19) United States
(12) Patent Application Publication
(10) Pub. No.: US 2026/0113903 A1
(43) Pub. Date: Apr. 23, 2026

(54) COOLING DISTRIBUTION UNIT

(71) Applicant: LTI Holdings, Inc., Pleasanton, CA (US)

(72) Inventor: Peter D. Bennett, Hampton, NH (US)

(21) Appl. No.: 19/359,954

(22) Filed: Oct. 16, 2025

Related U.S. Application Data
(60) Provisional application No. 63/709,119, filed on Oct. 18, 2024.
(60) Provisional application No. 63/709,115, filed on Oct. 18, 2024.

(51) Int. Cl. H05K 7/20

(52) U.S. Cl. CPC H05K 7/20836; H05K 7/2079

(57) ABSTRACT

A cooling distribution unit includes a first control loop, a second control loop, a first pressure sensor, a second pressure sensor, and a controller. The second control loop includes an inlet and an outlet. The first pressure sensor is situated at the inlet and is configured to sense a pressure of the second fluid. The second pressure sensor is situated at the inlet and is configured to sense the pressure of the second fluid. The controller is configured to operate in a differential mode, detect failure of the first pressure sensor and the second pressure sensor, and operate, in response to the failure, in a flow mode. In the differential mode, the controller operates based on a difference in pressure of the second fluid between the inlet and the outlet. In the flow mode, the controller operates based on a flow rate of the second fluid.

### CROSS-REFERENCE TO RELATED APPLICATIONS

This application claims priority to U.S. Provisional Patent Application No. 63/709,119, filed October 18, 2024, and to U.S. Provisional Patent Application No. 63/709,115, filed October 18, 2024, the entire contents of each of which are incorporated herein by reference.

### FIELD

The present disclosure generally relates to cooling distribution units for directing heat away from electrical components.

### BACKGROUND

Cooling distribution units (commonly referred to as CDU’s) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a cooling distribution unit includes a first control loop, a second control loop, a first pressure sensor, a second pressure sensor, and a controller. The first control loop is configured to direct a first fluid through a cooling structure. The cooling structure removes heat from the first fluid. The second control loop is configured to direct a second fluid across a plurality of electrical components. The second control loop includes an inlet and an outlet. The first pressure sensor is situated at the inlet and is configured to sense a pressure of the second fluid. The second pressure sensor is situated at the inlet and is configured to sense the pressure of the second fluid. The controller is configured to operate in a differential mode, detect failure of the first pressure sensor and the second pressure sensor, and operate, in response to the failure, in a flow mode. In the differential mode, the controller operates based on a difference in pressure of the second fluid between the inlet and the outlet. In the flow mode, the controller operates based on a flow rate of the second fluid.

In accordance with another example, a cooling distribution unit includes a first control loop, a second control loop, a first pressure sensor, a second pressure sensor, and a controller. The first control loop is configured to direct a first fluid through a cooling structure. The cooling structure removes heat from the first fluid. The second control loop is configured to direct a second fluid across a plurality of electrical components. The second control loop includes an inlet and an outlet. The first pressure sensor is situated at the outlet and is configured to sense a pressure of the second fluid. The second pressure sensor is situated at the outlet and is configured to sense the pressure of the second fluid. The controller is configured to operate in a differential mode, detect failure of the first pressure sensor and the second pressure sensor, and operate, in response to the failure, in a flow mode. In the differential mode, the controller operates based on a difference in pressure of the second fluid between the inlet and the outlet. In the flow mode, the controller operates based on a flow rate of the second fluid.

In accordance with another example, a cooling distribution unit includes a first control loop, a second control loop, a first temperature sensor, a second temperature sensor, and a controller. The first control loop is configured to direct a first fluid through a cooling structure. The cooling structure removes heat from the first fluid. The second control loop is configured to direct a second fluid across a plurality of electrical components. The second control loop includes an inlet and an outlet. The first temperature sensor is situated at the inlet and is configured to sense a temperature of the second fluid. The second temperature sensor is situated at the inlet and is configured to sense the temperature of the second fluid. The controller is configured to operate in a first temperature mode, detect failure of the first temperature sensor and the second temperature sensor, and operate, in response to the failure, in a second temperature mode. In the first temperature mode, the controller operates based on the temperature of the second fluid being greater than or equal to a first temperature threshold. In the second temperature mode, the controller operates based on the temperature of the second fluid being greater than or equal to a second temperature threshold.

In accordance with another example, a cooling distribution unit includes: a first control loop configured to direct a first fluid through a cooling structure; a second control loop configured to direct a second fluid across a plurality of electrical components, wherein the second control loop includes an outlet and an inlet; a first pressure sensor situated at the outlet and configured to sense a pressure of the second fluid; a second pressure sensor situated at the inlet and configured to sense the pressure of the second fluid; a flow sensor configured to sense a flow rate of the second fluid; and a controller communicatively connected to the first pressure sensor, the second pressure sensor, and the flow sensor, the controller configured to: operate in a flow mode, wherein, in the flow mode, the controller operates based on the flow rate of the second fluid, detect a fault in the flow sensor, and in response to detecting the fault in the flow sensor, operate in a differential pressure mode, wherein, in the differential pressure mode, the controller operates based on a difference in pressure of the second fluid between the inlet and the outlet.

In some aspects, the controller is further configured to, in the flow mode, receive the flow rate of the second fluid from the flow sensor.

In some aspects, the controller is further configured to in the differential pressure mode, control a speed of a pump based on the difference in pressure of the second fluid between the inlet and the outlet.

In some aspects, the controller is further configured to, in the differential pressure mode, control the speed of the pump based on the difference in pressure of the second fluid between the inlet and the outlet and a target difference in pressure of the second fluid between the inlet and the outlet.

In some aspects, the controller is further configured to, in the flow mode, periodically record measurements from the first pressure sensor and the second pressure sensor, and in the differential pressure mode, determine the target difference in pressure based on a difference in pressure of the second fluid between the inlet and the outlet recorded prior to detecting the fault in the flow sensor.

In some aspects, the controller is configured to, in the differential pressure mode, determine the target difference in pressure as an average of a plurality of respective differences in pressure of the second fluid between the inlet and the outlet recorded prior to detecting the fault in the flow sensor.

In some aspects, the target difference in pressure is a default value associated with the differential pressure mode.

In some aspects, the controller is configured to detect the fault in the flow sensor by receiving a fault signal from the flow sensor.

In some aspects, the controller is configured to detect the fault in the flow sensor by detecting a disconnection of the flow sensor.

In some aspects, the controller is configured to detect the fault in the flow sensor by determining that a flow rate measurement from the flow sensor is outside a predetermined range.

In some aspects, the predetermined range is 0 to 176 gallons per minute.

In some aspects, the controller is further configured to, in response to detecting the fault, generate a notification indicating that the fault has been detected, and transmit the notification to an administrator device over a communication network.

In some aspects, the cooling distribution unit further includes a display, wherein the controller is further configured to, in response to detecting the fault, control the display to display a warning message indicating that the fault has been detected.

In some aspects, the controller is further configured to determine whether a secondary cooling distribution unit is available, and shut down, in response to determining that the secondary cooling distribution unit is available and in response to detecting the fault, operation of the cooling distribution unit.

In some aspects, the controller is further configured to determine whether a secondary cooling distribution unit is available, and operate in the differential pressure mode in response to determining that the secondary cooling distribution unit is not available and in response to detecting the fault.

In some aspects, the cooling distribution unit further includes a third pressure sensor situated at the outlet and configured to sense the pressure of the second fluid; and a fourth pressure sensor situated at the outlet and configured to sense the pressure of the second fluid.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

In the accompanying figures similar or the same reference numerals may be repeated to indicate corresponding or analogous elements. These figures, together with the detailed description, below are incorporated in and form part of the specification and serve to further illustrate various embodiments, examples, aspects, and features of concepts that include the claimed subject matter, and to explain various principles and advantages of those embodiments, examples, aspects, and features.

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a block diagram of a controller in accordance with one example.

FIG. 6 is a block diagram of an example method performed by the controller of FIG. 5.

FIG. 7 is a block diagram of an example method performed by the controller of FIG. 5.

FIG. 8 is a block diagram of an example method performed by the controller of FIG. 5.

FIG. 9 is a block diagram of an example method performed by the controller of FIG. 5.

FIG. 10 is a block diagram of an example method performed by the controller of FIG. 5.

FIG. 11 is a graphical user interface for the cooling distribution unit of FIG. 1 in accordance with one example.

FIG. 12 is a circuit diagram of a transformer implemented in the cooling distribution unit of FIG. 1 in accordance with one example.

FIG. 13 is a block diagram of another example method performed by the controller of FIG. 5.

FIG. 14 is a block diagram of another example method performed by the controller of FIG. 5.

Skilled artisans will appreciate that elements in the figures are illustrated for simplicity and clarity and have not necessarily been drawn to scale. For example, the dimensions of some of the elements in the figures may be exaggerated relative to other elements to help improve understanding of the examples, aspects, and features presented in this disclosure.

The system, apparatus, and method components have been represented where appropriate by conventional symbols in the drawings, showing only those specific details that are pertinent to understanding of the various embodiments, examples, aspects, and features of the present disclosure so as not to obscure the disclosure with details that will be readily apparent to those of ordinary skill in the art having the benefit of the description herein.

### DETAILED DESCRIPTION

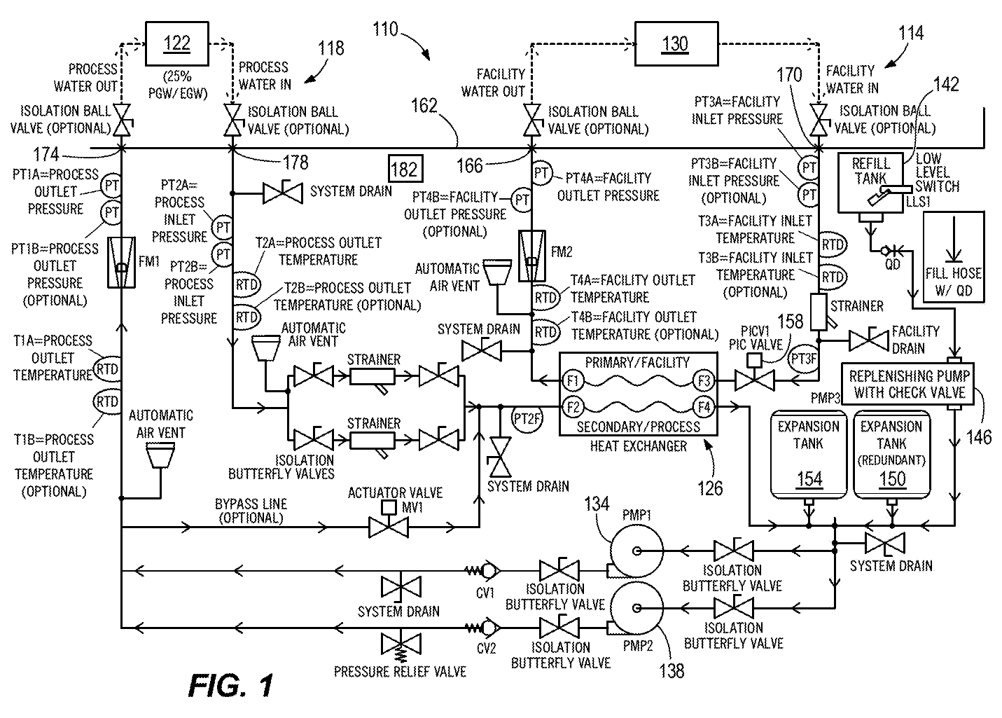

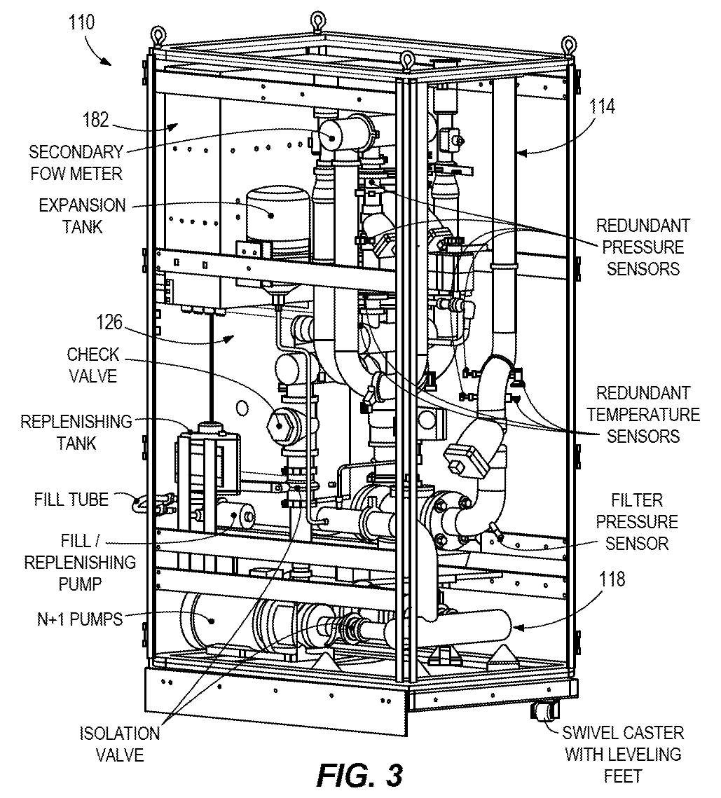

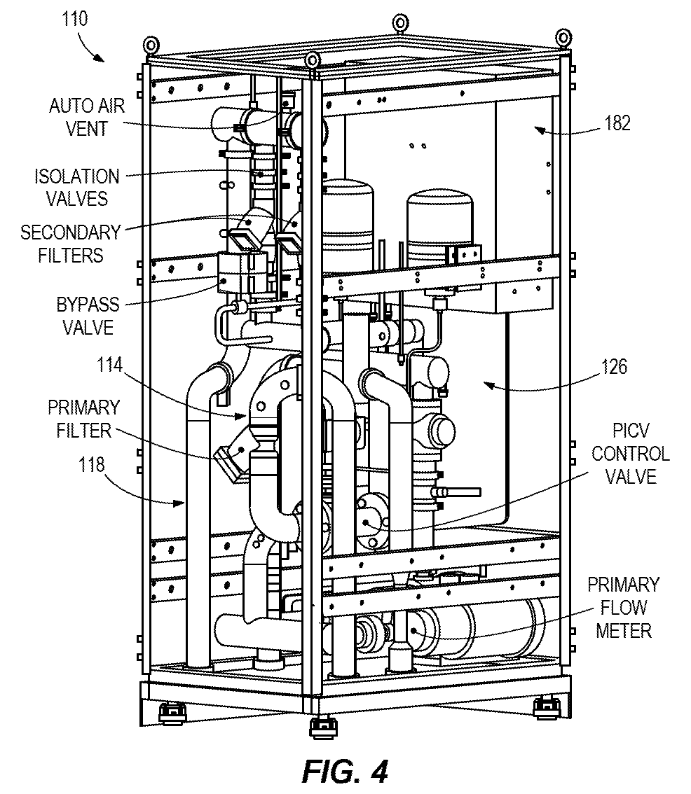

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

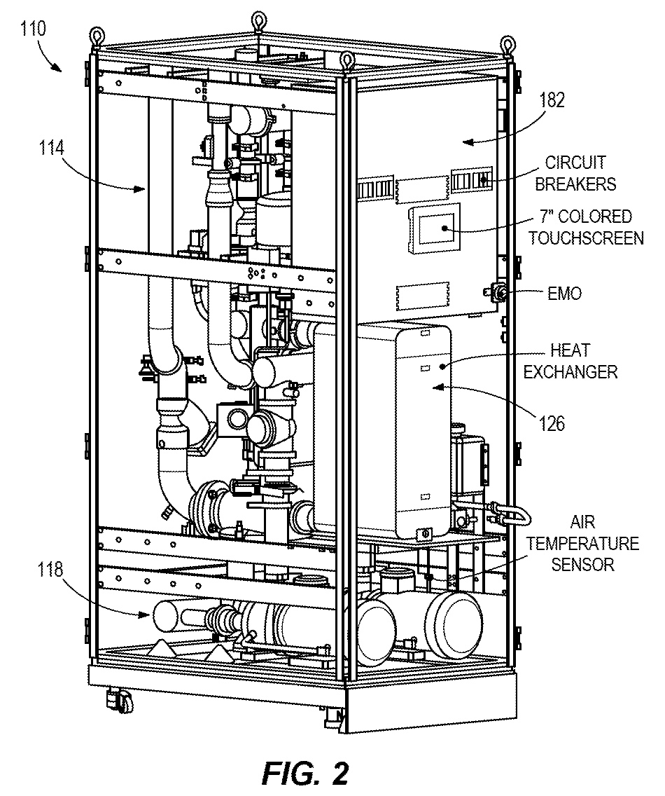

With reference to FIG. 1, the cooling distribution unit 110 generally includes a primary closed loop 114 (a first control loop) and a secondary closed loop 118 (a second control loop). The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. In some examples, at least a portion of the piping for the primary closed loop 114 and/or the secondary closed loop 118 is cylindrical in shape and/or has a circular cross-section. In some examples, at least a portion of the piping for the primary closed loop 114 and/or the secondary closed loop 118 has a linear section and/or a curved section. Other examples include other types of piping, including piping made of other materials (e.g., metal or non-metal), or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130. The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/ or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center), to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails 134, 138, the other may continue to operate the overall flow of the second fluid within the secondary closed loop 118. The first pump 134 and the second pump 138 may be any type of pump that is capable of pumping the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and also numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50GPM, 100GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 includes one or more doors (e.g., pivotally coupled or otherwise coupled to the frame). Other examples may include various other types, sizes, and/or shapes of housing 162 than that illustrated. In the illustrated example the housing 162 includes a first outlet 166 where the primary closed loop 114 exits, and the first fluid is sent to the cooling structure 130. The housing 162 also includes a first inlet 170, wherein the primary closed loop 114 enters, and wherein the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

In the illustrated example, the cooling distribution unit 110 has an overall dimension of 31.5” by 47.4” by 84.5”, and an overall weight of approximately 1400 pounds. Other examples may include various different sizes and weights, including sizes smaller and larger than that illustrated, and weights smaller or greater than that illustrated. Additionally, in the illustrated example, the cooling distribution unit 110 may provide a cooling capacity of 550kW (at 4ºC approach temperature difference) and 1100kW (at 8ºC approach temperature difference). Other examples may include other values and ranges of values of cooling capacity, including a cooling capacity smaller or greater than that illustrated.

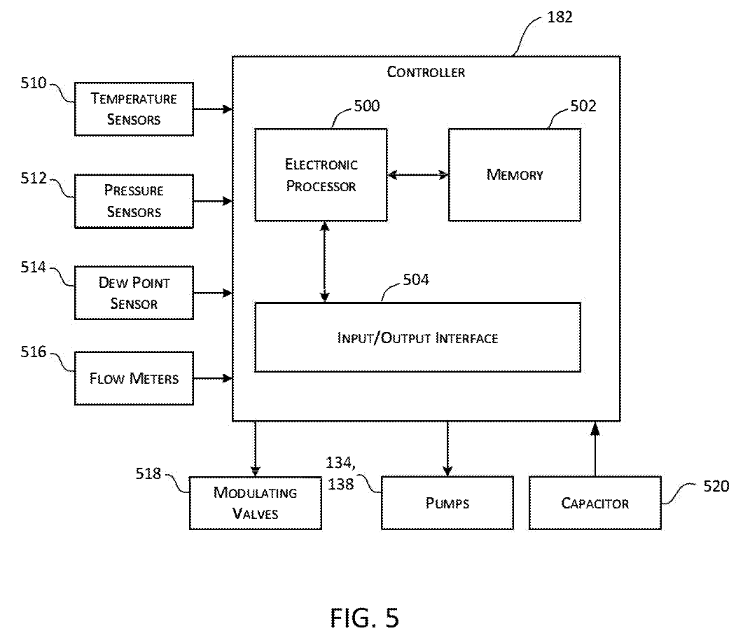

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. For example, the first outlet 166 is associated with a first primary-out fluid pressure sensor PT4A, a second primary-out fluid pressure sensor PT4B, a first primary-out fluid temperature sensor T4A, and a second primary-out fluid temperature sensor T4B. The first inlet 170 is associated with a first primary-in fluid pressure sensor PT3A, a second primary-in fluid pressure sensor PT3B, a primary in-fluid pressure sensor after strainer PT3F (situated after a strainer), a first primary-in fluid temperature sensor T3A, and a second primary-in fluid temperature sensor T3B. The second outlet 174 is associated with a first secondary-out fluid supply pressure sensor PT1A, a second secondary-out fluid supply pressure sensor PT1B, a first secondary-out fluid supply temperature sensor T1A, and a second secondary-out fluid supply temperature sensor T1B. The second inlet 178 is associated with a first secondary-in fluid return pressure sensor PT2A, a second secondary-in fluid return pressure sensor PT2B, a secondary in-fluid pressure sensor after strainer PT2F (situated after a strainer and adjacent to heat exchanger 126), a first secondary-in fluid return temperature sensor T2A, and a second secondary-in fluid return temperature sensor T2B. As illustrated in FIG. 1, the cooling distribution unit 110 may include redundant pressure and temperature sensors (e.g., in the event one or more of the sensors fails or provide inaccurate readings). Sensors may be provided in pairs (e.g., the first secondary-out fluid supply pressure sensor PT1A paired with the second secondary-out fluid supply pressure sensor PT1B) to provide a back-up (e.g., redundant) sensor in the situation where only a single sensor of the pair fails. The cooling distribution unit 110 may also include other types of sensors, such as dew point sensors 514 and/or the flow meters 516 (shown in FIG. 5). For example, a primary flow meter FM2 may be provided to detect the flow of first fluid exiting the first outlet 166 and a secondary flow meter FM1 may be provided to detect flow of second fluid exiting the second outlet 174.

In some examples, these sensors are coupled (e.g., wired or wirelessly) to a controller 182 (FIGS. 1-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

FIG. 5 illustrates a block diagram of the controller 182 of FIGS. 2-4 in accordance with some aspects. The controller 182 includes, among other things, an electronic processor 500, a memory 502, and an input/output (I/O) interface 504. The electronic processor 500, the memory 502, and the I/O interface 504 communicate over one or more control and/or data buses. FIG. 5 illustrates only one example of the controller 182. The controller 182 may include more or fewer components and may perform functions other than those explicitly described herein.

In some examples, the electronic processor 500 is implemented as a microcontroller with a separate memory, such as the memory 502. In other examples, the electronic processor 500 may be implemented as a microcontroller with memory 502 on the same chip. In other examples, the electronic processor 500 may be implemented partially or entirely as, for example, a field-programmable gate array (FPGA), an applications specific integrated circuit (ASIC), and the like and the memory 502 may not be needed or may be modified accordingly.

In the example illustrated, the memory 502 includes non-transitory, computer-readable memory (or medium) that stores instructions that are received and executed by the electronic processor 500 to carry out the functionality of the cooling distribution unit 110 described herein. For example, the electronic processor 500 may receive and execute instructions stored by the memory 502 to perform the method 600, the method 700, the method 800, the method 900, the method 1300, and/or the method 1400. The memory 502 may include, for example, a program storage area and a data storage area. The program storage area and the data storage area may include combinations of different types of memory, such as non-volatile read-only memory, non-volatile flash memory and volatile random-access memory.

The I/O interface 504 may include one or more input devices (e.g., a receiver, a keyboard, an interactable user interface, or the like) and one or more output devices (e.g., a transmitter, a display, or the like). In instances where the I/O interface 504 includes a display, the controller 182 may be configured to provide data regarding the operation of the cooling distribution unit 110 via the display. For example, data provided by sensors associated with the primary closed loop 114 (and therefore associated with the cooling structure 130) may be output via the display. Data provided by sensors associated with the secondary closed loop 118 may be used by the controller 182 to control operation of the cooling distribution unit 110.

The controller 182 receives feedback regarding the state of the cooling distribution unit 110 from temperature sensors 510 (e.g., T1A, T1B, T2A, T2B, T3A, T3B, T4A, T4B), pressure sensors 512 (e.g., PT1A, PT1B, PT2A, PT2B, PT3A, PT3B), dew point sensors 514, and flow meters 516. For example, the temperature sensors 510 are installed near the inlet and outlet locations of the primary closed loop 114 and the secondary closed loop 118 (e.g., the first outlet 166, the first inlet 170, the second outlet 174, and the second inlet 178). The temperature sensors 510 are configured to sense a fluid temperature at their respective locations. The temperature sensors 510 are configured to provide temperature signals to the controller 182 indicative of the fluid temperature.

The pressure sensors 512 are also installed near the inlet and outlet locations of the primary closed loop 114 and the secondary closed loop 118 (e.g., the first outlet 166, the first inlet 170, the second outlet 174, and the second inlet 178). The pressure sensors 512 are configured to sense (and in some examples measure) fluid pressure at their respective locations. The pressure sensors 512 are configured, in some examples, to provide pressure signals to the controller 182 indicative of the fluid pressure.

The dew point sensor 514 is configured to provide a dew signal to the controller 182 indicative of the current dew point temperature and the ambient air temperature. The flow meters 516 are installed on the first outlet 166 and the second outlet 174 lines and are configured to provide a flow signal to the controller 182 indicative of the flow rate of fluid exiting the housing 162 via the first outlet 166 and the second outlet 174.

The controller 182 may be configured to control modulating valves 518 to control the flow of fluid within the cooling distribution unit 110. For example, a modulating ball valve 518 may be situated at the first outlet 166, the first inlet 170, the second outlet 174 and/or the second inlet 178 to control the flow of fluid into and out of the primary closed loop 114 and/or the secondary closed loop 118. The controller 182 may be configured to additionally or alternatively control the pumps 134, 138 to control the flow of fluid within the cooling distribution unit 110.

In some instances, the controller 182 includes (or is electrically connected to) a capacitor 520. The capacitor 520 is configured to store energy that may be provided as power to the controller 182. In this manner, the capacitor 520 operates as a back-up power supply for the controller 182.

While only a single cooling distribution unit 110 is illustrated in FIGS. 1-4, in some examples, multiple cooling distribution units 110 may be provided in a system for cooling the electrical components 122 and/or other components within a system. When multiple cooling distribution units 110 are provided, the controller 182 may operate in a “Group Mode”, where the failure of one or more operational components within the cooling distribution unit 110 results in the controller 182 shutting down the cooling distribution unit 110. When the cooling distribution unit 110 experiencing the failure shuts down, the failed cooling distribution unit 110 is replaced with a functional cooling distribution unit 110 for cooling the electrical components 122.

However, in situations where the cooling distribution unit 110 is the only available cooling distribution unit 110 for cooling the electrical components 122, the controller 182 may operate in a “Single Mode”. In the “Single Mode” a failure of one or more operational components within the cooling distribution unit 110 may result in a shift in the operating mode of the cooling distribution unit 110 rather than a complete shut down. For example, should one or more sensors within the cooling distribution unit 110 fail, operation of the cooling distribution unit 110 is still desired. Accordingly, examples, aspects, and instances described herein provide for controlling the operation of the cooling distribution unit 110 in situations where one or more sensors fail or experience some errors. In this manner, cooling of the electrical components 122 are still provided even when every component of the cooling distribution unit 110 is not fully functional.

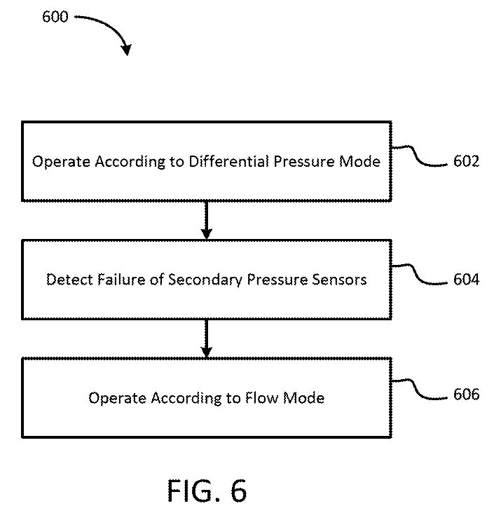

FIG. 6 illustrates a block diagram of a method 600 for adjusting an operating mode of the cooling distribution unit 110. The method 600 is described as being executed by the controller 182. However, in some examples, aspects of the method 600 may be performed by another processing device. Additionally, the various process blocks illustrated in FIG. 6 provide examples of various methods disclosed herein, and it is understood that some blocks may be removed, added, combined, or modified without departing from the spirit of the present disclosure. In the method 600, the controller 182 may be operating in the “Single Mode”, where a replacement cooling distribution unit 110 is not available.

At block 602, the controller 182 operates according to a differential pressure mode. In the differential mode, the controller 182 controls the modulating valves 518 and/or the pumps 134, 138 based on a differential pressure between second outlet 174 and the second inlet 178. The differential pressure may be calculated by determining a difference between pressure values indicated by pressure sensors at the second outlet 174 (e.g., the first secondary-out fluid supply pressure sensor PT1A and the second secondary-out fluid supply pressure sensor PT1B) and pressure values indicated by pressure sensors at the second inlet 178 (e.g., the first secondary-in fluid return pressure sensor PT2A and the second secondary-in fluid return pressure sensor PT2B). In some instances, the controller 182 controls the speed of the pumps 134, 138 based on the differential pressure.

At block 604, the controller 182 detects failure of the secondary pressure sensors. For example, both pressure sensors at the second outlet 174 (e.g., the first secondary-out fluid supply pressure sensor PT1A and the second secondary-out fluid supply pressure sensor PT1B) experience failures and no longer provide pressure signals (or, in some instances, provide inaccurate pressure signals). In another example, both pressure sensors at the second inlet 178 (e.g., the first secondary-in fluid return pressure sensor PT2A and the second secondary-in fluid return pressure sensor PT2B) experience failures and no longer provide pressure signals (or provide inaccurate pressure signals). Should either pair of pressure sensors fail, the differential pressure can no longer be calculated.

At block 606, the controller 182 operates according to a flow mode. For example, in response to the failure of the secondary pressure sensors, the controller 182 shifts the operating mode from the differential pressure mode to the flow mode. In the flow mode, the controller 182 controls the modulating valves 518 and/or the pumps 134, 138 based on a flow rate of fluid detected by the flow meters 516 (for example, based on the flow meter FM1 associated with the second outlet 174). Accordingly, should the pressure sensors experience a failure and no alternative cooling distribution unit 110 is available, the cooling distribution unit 110 continues to operate to cool the electrical components 122.

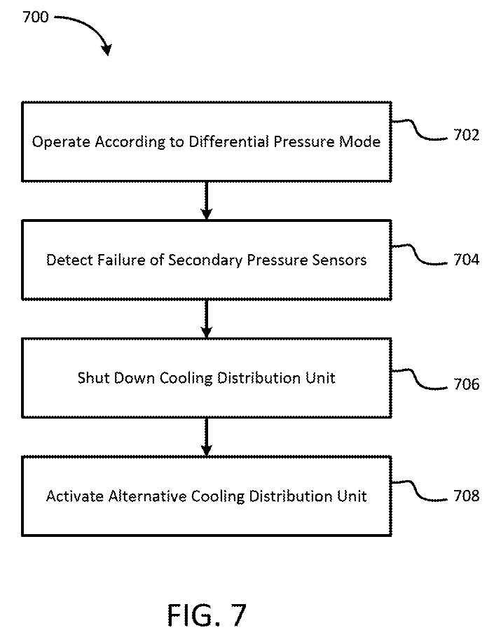

In some instances, an alternative cooling distribution unit 110 may be available. FIG. 7 illustrates a block diagram of a method 700 for adjusting an operating mode of the cooling distribution unit 110. The method 700 is described as being executed by the controller 182. However, in some examples, aspects of the method 700 may be performed by another processing device. Additionally, the various process blocks illustrated in FIG. 7 provide examples of various methods disclosed herein, and it is understood that some blocks may be removed, added, combined, or modified without departing from the spirit of the present disclosure. In the method 700, the controller 182 may be operating in the “Group Mode”, where a replacement cooling distribution unit 110 is available.

At block 702, the controller 182 operates according to the differential mode, as previously described with respect to block 602 of FIG. 6. At block 704, the controller 182 detects failure of the secondary pressure sensors, as previously described with respect to block 604 of FIG. 6.

At block 706, the controller 182 shuts down operation of the cooling distribution unit 110. For example, the modulating valves 518 and/or the pumps 134, 138 are controlled such that fluid no longer flows through the cooling distribution unit 110.

At block 708, the controller 182 activates an alternative cooling distribution unit 110. For example, the controller 182 transmits a signal to another cooling distribution unit 110, or some other server associated with the cooling distribution unit 110, to activate the alternative cooling distribution unit 110 such that the electrical components 122 continue to be cooled.

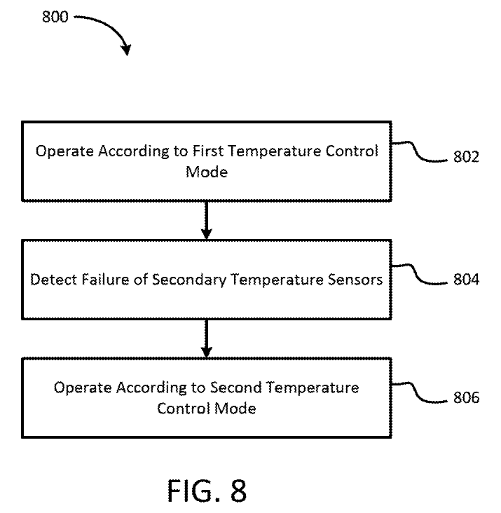

FIG. 8 illustrates a block diagram of a method 800 for adjusting an operating mode of the cooling distribution unit 110. The method 800 is described as being executed by the controller 182. However, in some examples, aspects of the method 800 may be performed by another processing device. Additionally, the various process blocks illustrated in FIG. 8 provide examples of various methods disclosed herein, and it is understood that some blocks may be removed, added, combined, or modified without departing from the spirit of the present disclosure. In the method 800, the controller 182 may be operating in the “Single Mode”, where a replacement cooling distribution unit 110 is not available.

At block 802, the controller 182 operates according to a first temperature control mode. For example, in the first temperature control mode, the controller 182 operates using the first secondary-out fluid supply temperature sensor T1A and the second secondary-out fluid supply temperature sensor T1B as inputs for control operations. The first secondary-out fluid supply temperature sensor T1A and the second secondary-out fluid supply temperature sensor T1B may be used to determine a current temperature of the second fluid provided to the electrical components 122 via the second outlet 174. For example, the temperature indicated by temperature signals from the first secondary-out fluid supply temperature sensor T1A and the second secondary-out fluid supply temperature sensor T1B is compared to a threshold. The modulating valves 518 and/or the pumps 134, 138 are then controlled according to the current temperature of the second fluid (e.g., whether the temperature indicated by first secondary-out fluid supply temperature sensor T1A and the second secondary-out fluid supply temperature sensor T1B is greater than or equal to a threshold).

At block 804, the controller 182 detects a failure of the secondary temperature sensors. For example, the controller 182 detects a failure of the first secondary-out fluid supply temperature sensor T1A and the second secondary-out fluid supply temperature sensor T1B. When failed, the first secondary-out fluid supply temperature sensor T1A and the second secondary-out fluid supply temperature sensor T1B may no longer provide temperature signals or may provide inaccurate temperature signals.

At block 806, the controller 182 operates according to a second temperature control mode. For example, in response to the failure of the secondary temperature sensors, the controller 182 shifts the operating mode from the first temperature control mode to the second temperature control mode. In the second temperature control mode, the controller 182 operates using the first secondary-in fluid return temperature sensor T2A and the second secondary-in fluid return temperature sensor T2B as inputs for control operations. The first secondary-in fluid return temperature sensor T2A and the second secondary-in fluid return temperature sensor T2B may be used to determine a current temperature of the second fluid that has passed over the electrical components 122 and passes through the second inlet 178. In some instances, the controller 182 operates to achieve a temperature of the second fluid at the second inlet 178 that is some second threshold value greater than the temperature measured in the primary closed loop 114 (e.g., the temperature measured by the first primary-in fluid temperature sensor T3A and the second primary-in fluid temperature sensor T3B). The second threshold value may be, for example, 6°C, 8°C, 10°C, 12°C, or the like. Accordingly, should the temperature sensors experience a failure and no alternative cooling distribution unit 110 is available, the cooling distribution unit 110 continues to operate to cool the electrical components 122.

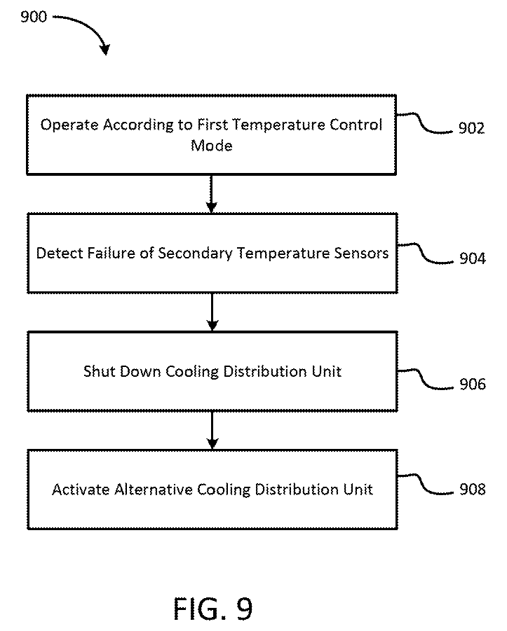

In some instances, an alternative cooling distribution unit 110 may be available. FIG. 9 illustrates a block diagram of a method 900 for adjusting an operating mode of the cooling distribution unit 110. The method 900 is described as being executed by the controller 182. However, in some examples, aspects of the method 900 may be performed by another processing device. Additionally, the various process blocks illustrated in FIG. 9 provide examples of various methods disclosed herein, and it is understood that some blocks may be removed, added, combined, or modified without departing from the spirit of the present disclosure. In the method 900, the controller 182 may be operating in the “Group Mode”, where a replacement cooling distribution unit 110 is available.

At block 902, the controller 182 operates according to the differential mode, as previously described with respect to block 802 of FIG. 8. At block 904, the controller 182 detects failure of the secondary temperature sensors, as previously described with respect to block 804 of FIG. 8.

At block 906, the controller 182 shuts down operation of the cooling distribution unit 110. For example, the modulating valves 518 and/or the pumps 134, 138 are controlled such that fluid no longer flows through the cooling distribution unit 110.

At block 908, the controller 182 activates an alternative cooling distribution unit 110. For example, the controller 182 transmits a signal to another cooling distribution unit 110, or some other server associated with the cooling distribution unit 110, to activate the alternative cooling distribution unit 110 such that the electrical components 122 continue to be cooled.

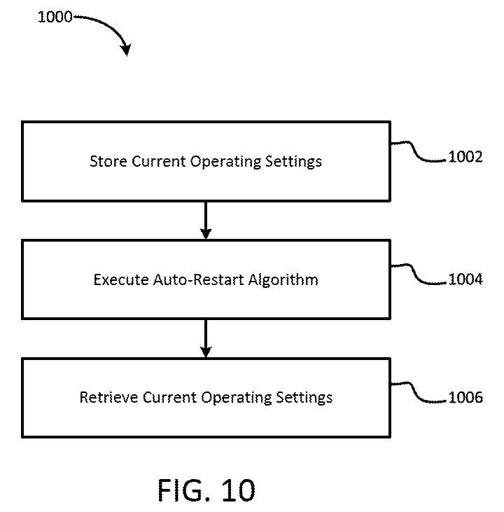

FIG. 10 illustrates a flow diagram for a method 1000 of operating the cooling distribution unit 110. The method 1000 is described as being executed by the controller 182. However, in some examples, aspects of the method 1000 may be performed by another processing device. Additionally, the various process blocks illustrated in FIG. 10 provide examples of various methods disclosed herein, and it is understood that some blocks may be removed, added, combined, or modified without departing from the spirit of the present disclosure.

During operation, at block 1002, the method 1000 includes storing current operating settings in, for example, the memory 502. In one example operating settings are continuously stored in the memory 502.

In the event of a power interruption, at block 1004, the method 1000 includes executing an auto-restart algorithm. The auto-restart algorithm begins when a drop in and/or loss of power is detected for a given amount of time.

At block 1006, the method 1000 includes retrieving the most recent operating settings from the memory 502. Accordingly, in an event where the drop in and/or loss of power is detected, the cooling distribution unit 110 acquires the previous operating settings.

The capacitor 520 (FIG. 5) is configured to store enough energy to provide power to the controller 182 (and, in some instances, other components of the cooling distribution unit 110) for a given amount of time. In one example, the cooling distribution unit 110 can undergo a full second of power loss with no intervention required. Accordingly, the controller 182 continues to receive power via the capacitor 520 even during a power loss.

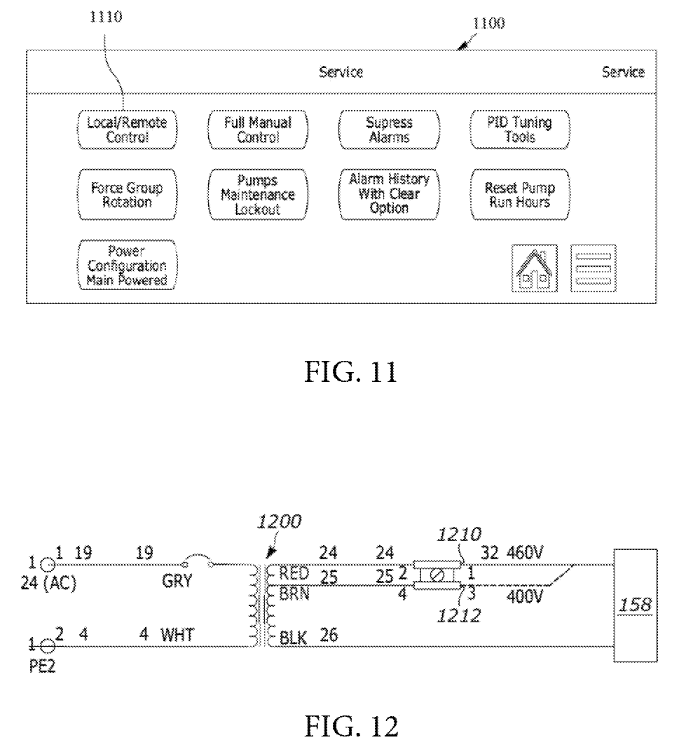

In one example, the auto-restart algorithm is implemented when the cooling distribution unit 110 is in a remote mode. FIG. 11 illustrates a service menu 1100 for the cooling distribution unit 110 displayed on, by way of example, a graphical user interface provided by the I/O interface 504. A user may select a local/remote control button 1110 to toggle between a local control mode and a remote-control mode. In one example when the local/remote control button is selected, a local control is active. An option for setting a local control time-out may be provided. If the local control time-out is activated, after the time-out has passed, the cooling distribution unit 110 may switch to the remote-control mode. If the local control time-out is not activated, the cooling distribution unit 110 may remain in the local control mode unless manually set to remote control mode.

Turning to FIG. 12, in one example the cooling distribution unit 110 contains a transformer 1200 which provides 24 VAC power to the pressure independent control valve 158. For 380V or 400V of incoming power a 400V tap terminal 1210 of the transformer 1200 is connected to the pressure independent control valve 158. For 460V or 480V incoming power a 460V tap terminal 1212 of the transformer 1200 is connected to the pressure independent control valve 158.

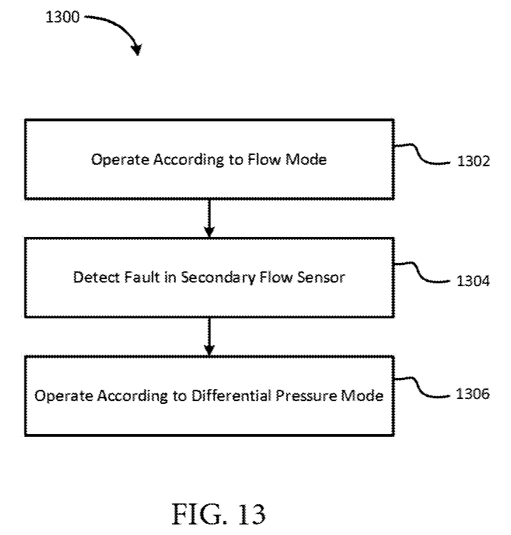

FIG. 13 illustrates a block diagram of another method 1300, for adjusting an operating mode of the cooling distribution unit 110. The method 1300 is described as being executed by the controller 182. However, in some examples, aspects of the method 1300 may be performed by another processing device. Additionally, the various process blocks illustrated in FIG. 13 provide examples of various methods disclosed herein, and it is understood that some blocks may be removed, added, combined, or modified without departing from the spirit of the present disclosure. In the method 1300, the controller 182 may be operating in the “Single Mode”, where a replacement cooling distribution unit 110 is not available.

At block 1302, the controller 182 operates according to a flow mode. In the flow mode, the controller 182 controls the modulating valves 518 and/or the pumps 134, 138 based on a flow rate of fluid detected by the flow meters 516 (for example, based on the flow meter FM1 associated with the second outlet 174). For example, based on measurements from the flow meter FM1, the controller 182 may increase, decrease, or maintain a speed of the pumps 134, 138 to achieve a desired flow rate. The desired flow rate may be a predetermined flow rate or flow rate range associated with the flow mode, or may be a user-selected flow rate. In some instances, the controller determines the desired flow rate based on a sensed temperature of the second fluid in the secondary closed loop 118.

At block 1304, the controller 182 detects fault in the secondary flow meter FM1. For example, the controller 182 may detect the fault by receiving a fault signal from the secondary flow meter FM1, or by detecting a communicative disconnection of the secondary flow meter FM1 from the controller 182. In some instances, the controller 182 detects the fault in the secondary flow meter FM1 by determining that a flow rate measurement from the secondary flow meter FM1 is outside a predetermined range. For example, the predetermined range may be 0 to 150 GPM, 0 to 175 GPM, 0 to 176 GPM, 0 to 200 GPM, or the like. The predetermined range may vary according to a flow capacity of the components of the secondary closed loop 118. The predetermined range may be a range that is wider than an achievable range of operation of the cooling distribution unit 110. In this manner, a flow rate measurement outside the predetermined range may indicate a failure in the flow meter FM1 itself, rather than a failure in, for example, the pumps 134, 138.

At block 1306, the controller 182 operates according to a differential pressure mode. For example, in response to detecting the fault in the flow meter FM1, the controller 182 shifts the operating mode from the flow mode to the differential pressure mode. In the differential pressure mode, the controller 182 controls the modulating valves 518 and/or the pumps 134, 138 based on a differential pressure between second outlet 174 and the second inlet 178. The differential pressure may be calculated by determining a difference between pressure values indicated by pressure sensors at the second outlet 174 (e.g., the first secondary-out fluid supply pressure sensor PT1A and the second secondary-out fluid supply pressure sensor PT1B) and pressure values indicated by pressure sensors at the second inlet 178 (e.g., the first secondary-in fluid return pressure sensor PT2A and the second secondary-in fluid return pressure sensor PT2B). In some instances, the controller 182 operates according to a differential pressure mode in response to detecting the fault in the secondary flow meter FM2 and in response to determining that an alternative cooling distribution unit 110 is not available.

In the differential pressure mode, the controller 182 may control the modulating valves 518 and/or the pumps 134, 138 to achieve a desired, or target, differential pressure between second outlet 174 and the second inlet 178. For example, based on the measured differential pressure between second outlet 174 and the second inlet 178, the controller 182 may increase, decrease, or maintain a speed of the pumps 134, 138 to achieve a target differential pressure. In some instances, the target differential pressure is a default value or range of values associated with the differential pressure mode.

In some instances, the controller 182 determines the target differential pressure to maintain the approximate flow rate prior to detecting the fault in the secondary flow meter FM1. For example, during operation in the flow mode (e.g., prior to detecting the fault at block 604), the controller 182 may periodically receive and store (e.g., in the memory 502) pressure measurements from the pressure sensors at the second outlet 174 and the second inlet 178. In the differential pressure mode, the controller 182 may determine the target differential pressure based on a difference in pressure of the second fluid between the second outlet 174 and the second inlet 178 recorded prior to detecting the fault in the secondary flow meter FM1. For example, the controller 182 may determine the target differential pressure based on the last recorded pressure readings of the pressure sensors before failure of the secondary flow meter FM1.

In some instances, the controller 182 determines the target differential pressure as an average of a plurality of respective differences in pressure of the second fluid between the second outlet 174 and the second inlet 178 recorded prior to detecting the fault in the flow sensor. The plurality of respective differences in pressure may corresponding to a predetermined number of pressure readings or a predetermined time prior to detection of the fault in the secondary flow meter FM1.

In some instances, the controller 182 also generates a notification indicating that the fault has been detected in the secondary flow meter FM2. For example, the controller 182 may transmit the notification (e.g., over a communication network) to an administrator device associated with the cooling distribution unit 110. In some instances, the controller 182 controls a display of the cooling distribution unit 110 to display a warning message indicating that the fault has been detected.

Accordingly, should the flow meter FM1 experience a failure and no alternative cooling distribution unit 110 is available, the cooling distribution unit 110 continues to operate to cool the electrical components 122.

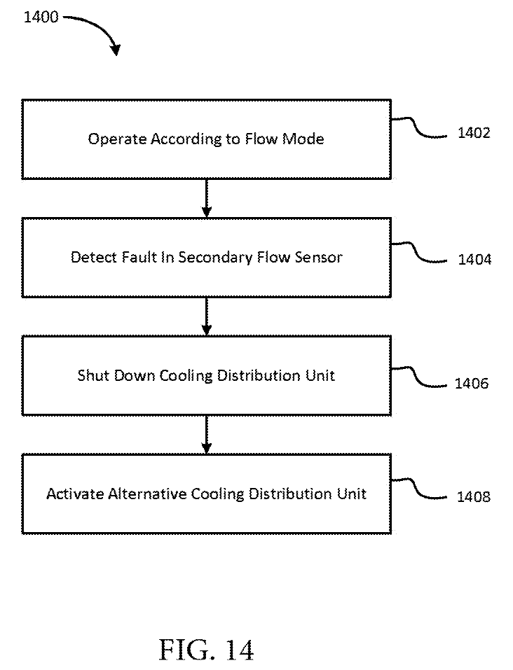

In some instances, an alternative cooling distribution unit 110 may be available. FIG. 14 illustrates a block diagram of a method 1400 for adjusting an operating mode of the cooling distribution unit 110. The method 1400 is described as being executed by the controller 182. However, in some examples, aspects of the method 1400 may be performed by another processing device. Additionally, the various process blocks illustrated in FIG. 14 provide examples of various methods disclosed herein, and it is understood that some blocks may be removed, added, combined, or modified without departing from the spirit of the present disclosure. In the method 1400, the controller 182 may be operating in the “Group Mode”, where a replacement cooling distribution unit 110 is available.

At block 1402, the controller 182 operates according to the flow mode, as previously described with respect to block 602 of FIG. 13. At block 1404, the controller 182 detects failure of the secondary flow meter FM1, as previously described with respect to block 1304 of FIG. 13.

At block 1406, the controller 182 shuts down operation of the cooling distribution unit 110. For example, the modulating valves 518 and/or the pumps 134, 138 are controlled such that fluid no longer flows through the cooling distribution unit 110. The controller 182 may shut down operation of the cooling distribution unit in response to determining that an alternative cooling distribution unit 110 is available.

At block 1408, the controller 182 activates the alternative cooling distribution unit 110. For example, the controller 182 transmits a signal to another cooling distribution unit 110, or some other server associated with the cooling distribution unit 110, to activate the alternative cooling distribution unit 110 such that the electrical components 122 continue to be cooled.

In the foregoing specification, specific examples have been described. However, one of ordinary skill in the art appreciates that various modifications and changes may be made without departing from the scope of the disclosure as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The disclosure is defined solely by the appended claims including any amendments made during the pendency of this application and all equivalents of those claims as issued.

In this document relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus.

should also be noted that a plurality of hardware and software-based devices, as well as a plurality of different structural components may be utilized in various implementations. Aspects, features, and instances may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one instance, the electronic based aspects of the disclosure may be implemented in software (for example, stored on non-transitory computer-readable medium) executable by one or more processors. As a consequence, it should be noted that a plurality of hardware and software-based devices, as well as a plurality of different structural components may be utilized to implement the disclosure. For example, “control units” and “controllers” described in the specification can include one or more electronic processors, one or more memories including a non-transitory computer-readable medium, one or more input/output interfaces, and various connections (for example, a system bus) connecting the components.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

should also be understood that although certain drawings illustrate hardware and software located within particular devices, these depictions are for illustrative purposes only. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all the multiple determinations collectively. To reiterate, those electronic processors and processing may be distributed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A cooling distribution unit (110) comprising:
a first control loop (114) configured to direct a first fluid through a cooling structure (130), wherein the cooling structure removes heat from the first fluid;
a second control loop (118) configured to direct a second fluid across a plurality of electrical components (122), wherein the second control loop (118) includes an inlet (174) and an outlet (178);
a first pressure sensor situated at the inlet (174) and configured to sense a pressure of the second fluid;
a second pressure sensor situated at the inlet (174) and configured to sense the pressure of the second fluid; and
a controller (182) configured to:
operate in a differential mode, wherein, in the differential mode, the controller operates based on a difference in pressure of the second fluid between the inlet (174) and the outlet (178),
detect failure of the first pressure sensor and the second pressure sensor, and
operate, in response to the failure, in a flow mode, wherein, in the flow mode, the controller (182) operates based on a flow rate of the second fluid.

2. The cooling distribution unit (110) of claim 1, further comprising:
a third pressure sensor situated at the outlet (178) and configured to sense the pressure of the second fluid; and
a fourth pressure sensor situated at the outlet (178) and configured to sense the pressure of the second fluid.

3. The cooling distribution unit (110) of claim 1, further comprising:
a flow sensor configured to sense a flow rate of the second fluid passing the inlet (174).

4. The cooling distribution unit (110) of claim 3, wherein, in the flow mode, the controller (182) receives the flow rate of the second fluid from the flow sensor.

5. The cooling distribution unit (110) of claim 3, wherein the controller is configured to detect a fault in the flow sensor, and in response to detecting the fault in the flow sensor, operate in a differential pressure mode.

6. The cooling distribution unit (110) of claim 5, wherein in the differential pressure mode, the controller operates based on a difference in pressure of the second fluid between the inlet (174) and the outlet (178).

7. The cooling distribution unit (110) of claim 1, wherein the controller (182) is further configured to:
determine whether a secondary cooling distribution unit is available; and
shut down, in response to the secondary cooling distribution unit being available and in response to the failure, operation of the cooling distribution unit (110).

8. The cooling distribution unit (110) of claim 1, wherein, in the differential mode, the controller (182) is further configured to:
control a speed of a pump (134, 138) based on the difference in pressure of the second fluid between the inlet (174) and the outlet (178).

9. A cooling distribution unit (110) comprising:
a first control loop (114) configured to direct a first fluid through a cooling structure (130), wherein the cooling structure removes heat from the first fluid;
a second control loop (118) configured to direct a second fluid across a plurality of electrical components (122), wherein the second control loop (118) includes an inlet (174) and an outlet (178);
a first pressure sensor situated at the outlet (178) and configured to sense a pressure of the second fluid;
a second pressure sensor situated at the outlet (178) and configured to sense the pressure of the second fluid; and
a controller (182) configured to:
operate in a differential mode, wherein, in the differential mode, the controller operates based on a difference in pressure of the second fluid between the inlet (174) and the outlet (178),
detect failure of the first pressure sensor and a second pressure sensor, and
operate, in response to the failure, in a flow mode, wherein, in the flow mode, the controller (182) operates based on a flow rate of the second fluid.

10. The cooling distribution unit (110) of claim 9, further comprising:
a third pressure sensor situated at the inlet (174) and configured to sense the pressure of the second fluid; and
a fourth pressure sensor situated at the inlet (174) and configured to sense the pressure of the second fluid.

11. The cooling distribution unit (110) of claim 9, further comprising:
a flow sensor configured to sense a flow rate of the second fluid passing the inlet (174).

12. The cooling distribution unit (110) of claim 11, wherein, in the flow mode, the controller (182) receives the flow rate of the second fluid from the flow sensor.

13. The cooling distribution unit (110) of claim 11, wherein the controller is configured to detect a fault in the flow sensor, and in response to detecting the fault in the flow sensor, operate in a differential pressure mode.

14. The cooling distribution unit (110) of claim 13, wherein in the differential pressure mode, the controller operates based on a difference in pressure of the second fluid between the inlet (174) and the outlet (178).

15. The cooling distribution unit (110) of claim 9, wherein the controller (182) is further configured to:
determine whether a secondary cooling distribution unit is available; and
shut down, in response to the secondary cooling distribution unit being available and in response to the failure, operation of the cooling distribution unit (110).

16. The cooling distribution unit (110) of claim 9, wherein, in the differential mode, the controller (182) is further configured to:
control a speed of a pump (134, 138) based on the difference in pressure of the second fluid between the inlet (174) and the outlet (178).

17. A cooling distribution unit (110) comprising:
a first control loop (114) configured to direct a first fluid through a cooling structure (130), wherein the cooling structure removes heat from the first fluid;
a second control loop (118) configured to direct a second fluid across a plurality of electrical components (122), wherein the second control loop (118) includes an inlet (174) and an outlet (178);
a first temperature sensor situated at the inlet (174) and configured to sense a temperature of the second fluid;
a second temperature sensor situated at the inlet (174) and configured to sense the temperature of the second fluid; and
a controller (182) configured to:
operate in a first temperature control mode, wherein, in the first temperature control mode, the controller (182) operates based on the temperature of the second fluid being greater than or equal to a first temperature threshold;
detect failure of the first temperature sensor and the second temperature sensor, and
operate, in response to the failure, in a second temperature control mode, wherein, in the second temperature control mode, the controller (182) operates based on the temperature of the second fluid being greater than or equal to a second temperature threshold.

18. The cooling distribution unit (110) of claim 17, wherein the controller (182) is further configured to:
determine whether a secondary cooling distribution unit is available; and
shut down, in response to the secondary cooling distribution unit being available and in response to the failure, operation of the cooling distribution unit (110).

19. The cooling distribution unit (110) of claim 17, further comprising:
a third temperature sensor situated at the outlet (178) and configured to sense the temperature of the second fluid; and
a fourth temperature sensor situated at the outlet (178) and configured to sense the temperature of the second fluid.

20. The cooling distribution unit (110) of claim 19, wherein, in the first temperature control mode, the controller is configured to receive inputs from the first temperature sensor and the second temperature sensor, and wherein, in the second temperature control mode, the controller is configured to receive inputs from the third temperature sensor and the fourth temperature sensor.
